(19) United States
(12) Patent Application Publication
(10) Pub. No.: US 2025/0072124 A1
(43) Pub. Date: Feb. 27, 2025

(54) AN ELECTRODE ASSEMBLY

(71) Applicant: REC Solar PTE. Ltd., Singapore (SG)

(72) Inventors: Thiyagu SUBRAMANI, Singapore (SG); Noel Gonzales Diesta, Singapore (SG); Shankar Gauri SRIDHARA, Singapore (SG)

(73) Assignee: REC Solar PTE. Ltd., Singapore (SG)

(21) Appl. No.: 18/725,566

(22) PCT Filed: Dec. 9, 2022
(86) PCT No.: PCT/EP2022/085155

§ 371 Date: Jun. 28, 2024

(30) Foreign Application Priority Data
Dec. 29, 2021 (GB) 2119065.7

(51) Int. Cl. H01L 31/05

(52) U.S. Cl. CPC H01L 31/0508

(57) ABSTRACT

An electrode assembly for connecting a front surface of a first solar cell to a back surface of a second solar cell, the electrode assembly comprising: a plurality of conductive elements, wherein at least one of the conductive elements comprises: a first surface for contacting the front surface of the first solar cell; and a second surface for contacting the back surface of the second solar cell, the second surface being arranged opposite the first surface; wherein at least a portion of each of the first and second surfaces comprises a coating for connecting the respective surfaces of the at least one conductive element to a surface of the solar cell; wherein the second surface is configured to define a contact area which is substantially smaller than the contact area defined by the first surface.

### CROSS-REFERENCE TO RELATED APPLICATIONS

This application is a U.S. National Phase Patent Application based on International Patent Application No. PCT/EP2022/085155, filed Dec. 9, 2022; which claims priority to GB Patent Application No. 2119065.7, filed Dec. 29, 2021. The above referenced applications are incorporated herein by reference in their entirety as if fully set forth herein.

### FIELD OF THE DISCLOSURE

The present disclosure relates to an electrode assembly for a solar cell assembly, to a solar cell assembly and to a method of manufacturing a solar cell assembly.

### BACKGROUND

Solar modules for providing electrical energy from sunlight comprise an array of cells, each comprising a photovoltaic element, or substrate. The solar cells are typically connected so that electrical current is routed, via an electrical connector, from a front surface of one solar cell to a back surface of a second solar cell, or vice versa. Each of the electrical connectors comprises a plurality of electrically conductive elements (e.g. interconnecting wires) which form an electrical connection with electrodes arranged on the respective front and back surfaces of the solar cells.

A general aim for solar cell development is to attain high conversion efficiency balanced by a need for reduced production costs. Efforts to achieve this have focussed on the electrical connections between the solar cells.

One approach has been to provide foil-wire electrodes which connect directly to finger electrodes arranged on the surface of each solar cell. The foil-wire electrodes reduce electrical losses by minimising the impact of cell damage on the performance of the solar module. Furthermore, the use of foil-wire electrodes can also lead to a significant reduction in module production costs and optical losses arising from the light shading caused by configuring the solar cell's surfaces with conventional printed busbar electrodes.

However, despite these developments, there remains a need to improve the contact between the electrodes of the solar cells to increase their power conversion efficiency.

### SUMMARY

According to a first aspect of the invention there is provided an electrode assembly for connecting a front surface of a first solar cell to a back surface of a second solar cell. The electrode assembly comprises a plurality of conductive elements. At least one of the conductive elements comprises a first surface for contacting the front surface of the first solar cell and a second surface for contacting the back surface of the second solar cell. The second surface is arranged opposite the first surface. At least a portion of each of the first and second surfaces comprises a coating for connecting the respective surfaces of the at least one conductive element to a surface of the solar cell (e.g. the front and back solar cell surfaces). The second surface is configured to define a contact area (e.g. with the back surface of the second solar cell) which is substantially smaller than the contact area defined by the first surface (e.g. with the front surface of the first solar cell).

When the electrode assembly is in use, the first surface of the at least one conductive element may be arranged to contact the front surface of the first solar cell, and to face away from the back surface of the second solar. Accordingly, the second surface may be arranged to contact the back surface of the second solar cell, and to face away from the front surface of the first solar cell. The larger contact area defined by the first surface improves the connection between the coating and the front surface of the first solar cell. This improves electrode assembly to solar cell connectivity and thereby increases the Fill Factor of the solar cell assembly.

The coating may be configured to form an electrical and/or physical (e.g. mechanical) connection with a surface of the solar cells. The coating may be a solderable coating, i.e. a coating which is configured to solder the conductive element to a surface of the solar cell.

The second surface, which defines a smaller contact area, is configured to increase the scattering of light incident on the first solar cell's front surface. It's smaller dimensions also reduce shading of the front surface so that more light can be absorbed by the first solar cell.

The electrode assembly is advantageously configured so that the first surface of the conductive element faces away from the second solar cell's back surface. This arrangement may cause increased shading of light which is incident upon the back surface of the solar cell (e.g. because the conductive element's first surface has a larger surface area, relative to the second surface). However, any potential increase in light shading at the back surface of the solar cell has only a limited effect on the overall light absorption properties of the solar cell (e.g. because light is mostly incident upon the cell's front surface) and so does not significantly impact the solar cell's performance.

During the construction of the solar cell assembly, the electrode assembly may be connected (e.g. laminated) onto the respective front and back surfaces of the first and second solar cells. At least one of the first and second solar cells may be inverted such that their front surfaces are arranged to face in a substantially downward direction (e.g. substantially vertically down) and their back surfaces are arranged to face in a substantially upward direction (e.g. substantially vertically up). In this situation, the electrode assembly according to the present invention is advantageously configured to form robust and conductive electrical connections with the respective contact surfaces of the first and second solar cells.

In particular, the first surface of the conductive element is connectable to the downwardly facing front surface of the first solar cell. The connection may be formed by applying heat and pressure to the coating on the first surface to form a mechanical and electrical connection with the surface of the solar cell. The weight of the materials which are positioned vertically above the first surface of the conductive element (e.g., the solar cell arranged on top of the conductive element and/or other components of the solar cell assembly) may help to prevent the coating from flowing away from the contact interface with the first solar cell. In addition, the relatively larger contact area of the conductive element's first surface may prevent the coating from flowing away from the contact interface, due to gravity. In this way, the larger contact area of the first surface may retain the coating at the interface with the solar cell, which thereby ensures that a good electrical connection is formed.

The second surface of the conductive element is also connectable to the upwardly facing back surface of the second solar cell. In this case, the relatively smaller contact area of the conductive element's second surface causes the coating to flow, due to gravity, towards the interface between the second surface of the conductive element and the back surface of the second solar cell. This leads to a build-up, or pooling, of the coating at the interface with the second solar cell's back surface, which thereby ensures a good electrical connection is formed. In this way, the difference between the respective contact areas of the conductive element's first and second surfaces creates a physical gradient which preferentially directs the coating towards the respective interfaces with the solar cells' front and back surfaces. This effect is particularly advantageous in embodiments where the coating comprises a material (e.g., metal alloy) with a relatively low melting point (compared to the conductive element beneath the coating) which melts during lamination of the solar cell assembly components (e.g. as in foil-wire connection technology).

In general, the at least one conductive element is configured to provide an improved electrical pathway between the first and second solar cells, whilst also enhancing the light scattering and absorption conditions at the front surface of the first solar cell. Accordingly, the conductive element(s) reduce the contact resistivity of the electrode assembly which thereby increases the Fill Factor of the solar cell assembly. Put another way, the conductive elements are configured to reduce resistance losses which would otherwise occur due to the poor contact interface between the electrode assembly and the respective contact surfaces of the solar cells. As a result, the electrode assembly is able to increase the power output of the solar cell assembly (and therefore the solar module). Also, the improved electrical connections between the electrode assembly and solar cells thereby increases the reliability of the solar cell assembly, which extends the operational life of the solar module and reduces the associated maintenance costs.

Optional features will now be set out. These are applicable singly or in any combination with any aspect.

The front surface of the solar cell may define the surface of the solar cell upon which light is incident when the solar cell assembly is in use (e.g. the frontmost surface of the solar cell). The back surface of the solar cell will define the surface of the solar cell which is opposite the front surface (e.g. the backmost surface of the solar cell). The back surface of the solar cell may not be directly exposed to incident light during use. The solar cell assembly may be configured so that light transmitted (e.g. not absorbed) from front to back through the solar cell is then reflected back towards the solar cell's back surface, which provides a further opportunity for the light to absorbed.

The conductive element(s) may be configured to form an ohmic contact with an electrically conductive surface (e.g. an electrically conductive portion of a surface) of the solar cells. Each of the solar cells may comprise a layered structure which includes a photovoltaic element, as would be understood by the skilled person. The conductive surface(s) may comprise one or more finger electrodes that are arranged on (e.g. printed on) the solar cell's front and back surfaces to conduct away charge carriers that are generated by the layered structure.

It will be understood that the terms ‘conductive’ and ‘insulating’ as used herein, are expressly intended to mean electrically conductive and electrically insulating, respectively. The meaning of these terms will be particularly apparent in view of the technical context of the disclosure, being that of photovoltaic solar cell devices. It will also be understood that the term ‘ohmic contact’ is intended to mean a non-rectifying electrical junction (i.e. a junction between two conductors which exhibits a substantially linear current-voltage (I-V) characteristic).

Each of the conductive elements may comprise an elongate form, such as a wire or wire portion. The at least one, or each, conductive element may comprise a single integrally formed element (e.g. a wire). Configuring the conductive elements in this way removes the need to provide separate connections (such as copper ribbons) between neighbouring solar cells, which thereby reduces the number and complexity of manufacturing steps required to fabricate the solar cell assembly.

The conductive elements described herein may form part of a ‘foil-wire’ electrode assembly in which conductive elements are first held by a foil (e.g. a transparent insulating film) before being arranged on a surface of the solar cell (e.g. foil-wire connection technology). In such embodiments, the coating may be arranged on the first and/or second surfaces of the conductive elements (e.g., so as to define a solid coating), prior to attaching the conductive element to the foil. The coating may comprise a material which has a lower melting point compared to the underlying conductive element, such that the coating melts during lamination of the electrode assembly onto the solar cell.

Alternatively, the conductive elements may form part of a multi-bus bar electrode assembly in which the conductive elements are arranged on a surface of the solar cell (e.g., individually placed and held against the solar cell surface) before being soldered in place (e.g. to define multi-bus bar connection technology). When used in a multi-bus bar electrode assembly, the coating on the first and/or second surfaces of the conductive elements may define a solder (e.g. an electrically conductive solder material) which mechanically and electrically couples the conductive element to the solar cell surface. In embodiments, the conductive element may define two or more separate components (e.g. two or more wire portions) which are electrically coupled together to form a single conductive element. For example, the conductive element may comprise a first conductive element portion for contacting the front surface of the first solar cell, and a second conductive element portion for contacting the back surface of the second solar cell. Each of the first and second conductive element portions may comprise a first and second surface, as described above. The first and second conductive element portions may be electrically coupled together by a third conductive element portion (e.g. a copper ribbon) to allow current to flow between the first and second conductive element portions. The third conductive element portion may be substantially parallel or substantially perpendicular to the first and second conducting element portions.

The conductive element(s) may be formed of an electrically conductive material, such as a metallic or metallic alloy material, which may include at least one of Sn, Ag, Al, Au and Cu.

The first and second surfaces may define upper or lower surfaces of the conductive element(s). At least one, or each, of the first and second surfaces may extend in a longitudinal direction along the length of the conductive element. The first surface may be arranged on a directly opposite side of the conductive element to the second surface.

The contact area of the first surface may be defined, at least in part, by a width of the first surface which is placed in contact, or near contact, with the front surface of the solar cell. Similarly, the contact area of the second surface may be defined, at least in part, by a width of the second surface which is placed in contact, or near contact, with the back surface of the solar cell. In this way, the first surface may be configured with a contact width which is greater than the contact width of the second surface.

It will be understood that the first and second surfaces each define a surface (e.g. a planar or curved surface) of the conductive element. Such a surface is distinct form an edge of the conductive element which may form between two neighbouring surfaces. For example, when considering a wire having a triangular (e.g. triangle shaped) cross section, the base of the triangle may be considered to define a surface. However, the apex of the triangular cross section would be considered to define an edge which defines the join between two angled surfaces. As such, the triangular cross sectioned wire does not comprise a first and a second opposing surface, as defined according to the present invention. Accordingly, the at least one conductive element may not comprise a triangular (e.g. triangle shaped) cross section.

In embodiments, the respective first and second contact areas may also be defined, at least in part, by a length of the conductive element which, when in use, is configured to overlay the respective front and back surfaces of first and second solar cells. The electrode assembly may be configured such that the length of the conductive element which overlays the front surface of the first solar cell is substantially equal to the length of the conductive element which overlays the back surface of the second solar cell. In this situation, the contact areas may be substantially defined by the respective widths of the first and second surfaces.

The conductive element may be configured such that it comprises a cross sectional shape which is non-symmetrical about a central lateral plane of the conductive element (i.e. a plane which extends in a width wise, or horizontal, direction through the longitudinal axis of the conductive element). The, or each, conductive element may be configured such that it comprises a cross sectional shape which is symmetrical about a central vertical plane of the conductive element (i.e. a plane which extends in a depth wise, or vertical, direction through the longitudinal axis of the conductive element).

At least one, or each, of the conductive elements may comprise a substantially constant cross-section along its length.

Each conductive element may be arranged such that the first and second surfaces maintain their respective positions on the conductive element as the element connects between the first and second solar cells. Put another way, each conductive element may be configured so as not to comprise any axial twists or turns along its length.

At least one, or each, of the conductive element(s) may comprise a first surface which is substantially flat. In this way, the first surface may define a substantially planar surface which faces the front surface of the first solar cell. In embodiments, the first surface may be configured to be substantially parallel to the front surface of the first solar cell. The flat first surface may provide a planar contact area which can retain the coating at the interface with the solar cell surface, which thereby forms a better electrical contact.

The flat first surface is particularly advantageous in situations where the solar cells are inverted during the connection to the electrode assembly, as described above. In such situations, the first surface of the conductive element is arranged to face in a substantially upward direction (e.g. vertically up). As such, when heat and/or pressure is applied to the conductive elements to form the connection with the solar cell surface, the coating is supported on the flat surface, and thereby prevented from flowing due to gravity away from the contact interface with the solar cell surface. It will be appreciated that the above advantageous arrangement may be achieved with a first surface which is substantially non-convex (e.g. comprising a substantially flat or substantially concave surface with respect to the body of the conductive element).

The second surface of the at least one, or each, conductive element(s) may be substantially curved. The second surface may curve outwardly from the conductive element (e.g. the surface curves away from a longitudinal axis of the conductive element). The second surface may be substantially convex (e.g. convex with respect the body of the conductive element). The outwardly curved shape of the second surface may define an arc when viewed from a cross section of the conductive element. The outwardly curved shape may be configured such that it terminates at the first surface. In embodiments, the at least one conductive element may comprise a cross section shaped as an elliptical segment (e.g. major or minor), such as a circular segment (e.g. major or minor). In embodiments, the at least one conductive element may comprise a semi-elliptical cross section, such as a semi-circular cross section.

In embodiments, the second surface may be substantially flat. The first surface may be substantially parallel to the second surface. The second surface may be configured to be substantially parallel to the back surface of the second solar cell.

The at least one conductive element may comprise a third surface arranged between the first and second surfaces. The third surface may be configured to space apart the first surface from the second surface. The conductive element may comprise a fourth surface arranged opposite the third surface. At least one of the third and fourth surfaces may define a depth of the conductive element.

At least one of the third and fourth surfaces may be substantially flat. In embodiments, at least one, or each, of the conductive element(s) may comprise a cross sectional shape which defines a truncated triangle.

The at least one of the third and fourth surfaces may be substantially curved. At least one of the third and fourth surfaces may be configured to curve outwardly from conductive element (e.g. substantially convex). In embodiments, at least one, or each, of the conductive element(s) may comprise a cross sectional shape which defines a truncated elliptical segment (e.g. a truncated major or minor elliptical segment). In embodiments, the cross-sectional shape may define a truncated semi-circle.

It is to be understood that references to “curved” include a chain of straight portions arranged at an angle to each other, such that, whilst each portion is straight, the overall form of the chain is curved.

The coating (i.e. the solderable coating) may comprise an electrically conductive material having a melting point which is lower than that of the conductive element. The coating may comprise a metal alloy formed of at least two or more components. The coating alloy may be at least one of a lead based, tin based and bismuth-based alloy. The coating may comprise a 2-phase, 3-phase, or more complex metal alloy. The coating may be formed of a metal alloy comprising at least one of Sn, Ag, Bi, Cd, Ga, In, Pb, Sn, Ti, etc. The coating may also comprise an electrically conductive material which is formed of metallic or alloy particles embedded within an organic matrix.

The coating may be configured to substantially cover at least one, or each, of the first and second surfaces of the at least one conductive element(s). The coating may be configured to substantially cover each conductive element's first and second surfaces. For example, in embodiments where the conductive element(s) comprise a third surface, and/or a fourth surface, which separate the first and second surfaces, then at least one, or each, of the third and/or fourth surfaces may be at least partially coated by the coating. Each conductive element may be completely coated by the coating. In embodiments, the coating may be absent from a portion of the first surface and/or the second surface. In embodiments, the coating may be absent from at least a portion of the third surface and/or the fourth surface.

A first portion of the electrode assembly which contacts the front surface of the first solar cell may define a front connecting portion, or front connector, of the electrode assembly. A second portion of the electrode assembly which contacts the back surface of the second solar cell may define a back-connecting portion, or back connector of the electrode assembly.

A first portion of each of the plurality of conductive elements may define the front connector of the electrode assembly. A second portion of each of the plurality of conductive elements may define the back connector of the electrode assembly. Accordingly, at least one, or each, of the plurality of conductive elements may extend from the front connector to the back connector of the electrode assembly.

The conductive element(s) may be configured to bend along an axial direction of the conductive element(s) so as to allow the electrode assembly to be coupled between the respective front and back surfaces of the first and second solar cells (i.e. to allow the conductive element(s) to provide an electrical connection between the front and back connectors).

The first surface of the conductive element(s) of the back connector may be arranged to define a back surface (i.e. a backmost surface) of the electrode assembly. The second surface of the conductive element(s) of the front connector may be arranged to define a front surface (i.e. a frontmost surface) of the electrode assembly.

Each of the conductive elements may comprise a width, an axial length, and a depth. Each of the conductive elements may be configured such that its axial length is substantially greater than its width and/or depth. The width and axial length of the conductive elements may be measured in perpendicular directions aligned with a plane of the surface of the solar cell upon which the conductive elements are arranged (e.g. the front or back surface of the solar cell). The depth may be measured in a direction which is perpendicular to the same plane of the solar cell.

In embodiments, the at least one conductive element(s) may be configured such that its width is between 0.2 mm and 0.4 mm, at its widest point. The length of the at least one, or each, conductive element may depend on the length of the solar cell. In an exemplary arrangement, the conductive element(s) may be at least twice the length of the solar cell, optionally +/−10 mm. The depth (i.e., the thickness) of the at least one, or each, conductive element may be between 0.2 mm and 0.4 mm. In embodiments the depth of conductive element may be between 0.2 mm and 0.4 mm.

At least one, or each, of the plurality of conductive elements may be arranged in and/or on a film (e.g., a film portion). The film may be configured to be insulating and/or optically transparent. The film may be configured to provide adhesion between the solar cell and the conductive element so that the conductive element is correctly spaced on the solar cell. In this way, the film enables the conductive elements to be correctly aligned with the solar cell. The film may provide a mechanical connection between the conductive element and the solar cell. In an exemplary arrangement, the film may not cover all the respective front and/or back surface(s) of the solar cell.

The film may be configured such that at least a portion of at least one of the first and second surfaces of the at least one conductive element is exposed from the film to form an ohmic contact with the respective front and back surfaces of the first and second solar cells. For example, at least a portion of the conductive element's first surface may be exposed from the film and/or at least a portion of the conductive element's second surface may be exposed from the film. In embodiments, the film may be thinner than the at least one conductive element. For example, the conductive element may have a thickness (i.e., depth) of at least 0.2 mm and up to 0.4 mm, whereas the film may have a thickness of at least 0.07 mm and up to 0.12 mm.

As described above, the conductive elements of the front and back connectors may define, respectively, a first and second portion of the plurality of conductive elements. The first portion of the plurality of conductive elements may be arranged in or on a first film (e.g. insulating and/or optically transparent film). The second portion of the plurality of conductive elements may be arranged in or on a second film (e.g. insulating and/or optically transparent film). Accordingly, the first surface may be exposed from the first film to form an ohmic contact with the front surface of the first solar cell, and/or the second surface may be exposed from the second film to form an ohmic contact with the back surface of the second solar cell.

A third portion of the plurality of conductive elements may be arranged between the first and second portions of the plurality of conductive elements. The third portion may be configured to be arranged between the first and second solar cells when the electrode assembly is connected therebetween. The third portion may be configured such that the conductive elements in this portion are not arranged in a film (i.e. in contrast to the first and second portions).

At least one, or each, of the conductive elements may be disposed on a surface of the respective first and second films. Alternatively, or in addition, at least one of the conductive elements may be arranged at least partially within the film. In this way, the at least one conductive element may be embedded within the film such that a surface of the conductive element protrudes from the surface of the film.

When in use, the first film of the front connector may define a front film of the electrode assembly. Similarly, the second film of the back connector may define a back film of the electrode assembly. The front film may be configured such that at least a portion of the first surface of the front connector's conductive elements is exposed. The back film may be configured such that at least a portion of the second surface of the back connector's conductive elements is exposed.

The film (e.g. the front and/or back films) may be formed of a polymer material having a high ductility, good insulating characteristics, optical transparency and thermal stability, resistance to shrinkage. Exemplary polymer materials may comprise acetate, epoxy resin, fluororesin, polyamide resin, polysulfone, rayon, polyolefin, plastilene, rayonext, polyethylene terephthalate (PET), polyvinyl fluoride film and modified ethylene tetrafluoroethylene, etc. In an embodiment, at least one of the first and second film consist of a single layer of material; however, in some other embodiments, at least one of the first and second films comprise two or more layers wherein two or more of these layers may include different materials and/or material characteristics.

The surface of the film facing the conductive elements may be coated with a transparent adhesive. During fabrication of the solar cell assembly, heat and/or pressure may be applied to the film so that the adhesive softens to enable adherence of the film to the conductive elements due to an application of force. In this way, the wires may be at least partially embedded in the adhesive. In embodiments, the conductive elements may be partially embedded in the adhesive but not actually contact the film. The first and/or second film(s) may be configured to provide structural support for the conductive elements when the plurality of conductive elements are being handled, prior to being arranged onto the solar cell(s).

When the front and back connectors are assembled with their respective first and second solar cells, the associated film may deform to conform to the shape of the conductive elements sandwiched between the film and the solar cell. In other words, the surface of the film may be substantially planar in non-wire regions, and form ridges/protuberances over the conductive elements in the wire regions. In this way, each (e.g. longitudinal) conductive element contacting region of the film may have a non-planar (e.g. transverse) profile.

The film of the front connector may have a back surface (i.e. facing towards the solar cell), and a front surface (i.e. facing away from the solar cell) opposite the back surface. At least one conductive element of the first portion of the plurality of conductive elements may be disposed on the back surface of the front film.

The film of the back connector may have a front surface (i.e. facing towards the solar cell), and a back surface (i.e. facing away from the solar cell) opposite the front surface. At least one conductive element of the second portion of the plurality of conductive elements may be disposed on the front surface of the back film.

According to a second aspect of the invention there is provided a solar cell assembly comprising a first solar cell, a second solar cell and an electrode assembly according to any one of preceding statements. The plurality of conductive elements may be configured to electrically couple a front surface of the first solar cell with a back surface of the second solar cell.

Each of the first and second solar cells may comprise a length, a width, and a depth. The length of the solar cell may be less than its width, and the depth may be less than both the width and the length. The longitudinal and transverse directions across the front and back surfaces of the solar cell may be parallel with the length and width directions of the solar cell, respectively. Hence, the plurality of conductive elements may be configured to extend across the length of the solar cell, and to be spaced along its width.

Each of the conductive elements may be configured to extend lengthwise relative to the surface of the solar cell upon which it is overlaid, in a longitudinal direction. The conductive elements may be spaced apart in a transverse direction relative to the solar cell surface to define longitudinal-extending spaces between the conductive elements. The conductive elements may be parallel or substantially parallel to one another. The conductive elements may be equally or substantially equally spaced in the transverse direction. Accordingly, the plurality of conductive elements may form an array of parallel, transversely spaced (e.g. equally spaced) conductive elements.

The electrode assembly may be configured to form an electrical connection with a conductive surface (or a conductive portion of a surface) of the first and second solar cells. As described above, the conductive elements of the electrode assembly are configured to optimise the optoelectronic properties of the front and/or back connectors, e.g. their electric current collection and solar cell shading characteristics.

Each of the solar cells' conductive surface(s) may comprise a plurality of finger electrodes which extend across the respective solar cell surfaces. The finger electrodes may be formed using a printed material, which enables them to be conveniently deposited onto the surfaces of the solar cells.

Each finger electrode of the pluralities of front and/or back finger electrodes may be configured with an axial length which is substantially greater than its width. Both the width and axial length of the finger electrode may be measured in perpendicular directions in the plane of the respective surface of the solar cell. The finger electrodes may extend in a transverse direction which is parallel with the width direction of the solar cell.

The finger electrodes within each of the pluralities of front and/or back finger electrodes may be spaced apart across the respective surface to define transversely extending spaces between the finger electrodes. The finger electrodes may be spaced apart in a longitudinal direction which is substantially parallel with the length direction of the solar cell. The finger electrodes in each plurality may be substantially parallel to one another.

The axial length of at least one finger electrode of the plurality of back finger electrodes may be substantially misaligned (e.g. substantially non-parallel or substantially perpendicular) with the axial length of at least one of the conductive elements of the electrode assembly, which is overlaid upon it. Accordingly, the conductive elements of the electrode assembly may be configured to extend across the surface of the solar cell to form an ohmic contact with each of the plurality of finger electrodes.

The axial length of the finger electrode may be arranged substantially perpendicular with respect to the axial lengths of the overlaid conductive element. In this way, the conductive elements can be conveniently arranged to optimise the charge collection from the surface of the solar cell. Where a finger electrode is axially misaligned with an overlaid conductive element, then the axial length of an associated finger electrode may be axially misaligned with each of the conductive elements by the same angle of misalignment, and vice versa.

The solar cell of the solar cell assembly may comprise a plurality of layers, or elements, including a photovoltaic element, wherein at least one of the plurality of layers is formed of a semiconductor material. The photovoltaic element (or layer) may be formed of a crystalline silicon wafer.

It will be appreciated that the solar cell may be configured to define any type of solar cell structure. For example, the solar cell may define a heterojunction type solar cell. Alternatively, the solar cell may define a tandem junction solar cell.

The surface(s) of the solar cell may be textured to form a textured surface corresponding to an uneven surface or having uneven characteristics. In this instance, an amount of light incident on the solar cell increases because of the textured surface of the solar cell, and thus the efficiency of the solar cell is improved.

The solar cell may further comprise an anti-reflection layer, or coating, arranged at the front and/or back surfaces of the solar cell. The, or each, anti-reflection layer may have a single-layered structure or a multi-layered structure. The anti-reflection layer may be formed of silicon nitride (SiNx) and/or silicon oxide (SiOx). Alternatively, the anti-reflection layer may be formed of a transparent conductive oxide (TCO), such as indium tin oxide (ITO), which has been textured to provide an anti-reflective surface. The anti-reflection layer advantageously reduces the reflectance of light incident on the solar cell and increases selectivity of a predetermined wavelength band, thereby increasing the efficiency of the solar cell.

The solar cell may comprise a transparent conductive oxide coating arranged at the front and/or back surfaces of the solar cell. The transparent conductive oxide coating may be configured to increase lateral carrier transport to finger electrodes arranged on the respective surfaces of the solar cell.

According to an exemplary arrangement, the conductive elements may at least in part form the electrode assembly which is applied to the first and second solar cells to define the solar cell assembly. Furthermore, one or more solar cell assemblies according to the present invention may be electrically coupled together and arranged in a housing to define a solar module.

According to an exemplary arrangement, a second electrode assembly may be provided to couple the front surface of the second solar cell to the back surface of a third solar cell. The conductive elements in the second electrode assembly may be as described above for the first electrode assembly. In this situation, the second and third solar cells may be combined with the second electrode assembly to define a second solar cell assembly. The conductive elements of the back connector of the first electrode assembly may be aligned with the conductive elements of the front connector of the second electrode assembly, with the second solar cell interposed therebetween.

The solar module may comprise a frame in which to house the plurality of solar cell assemblies. The frame may comprise a front plate and a back plate which are arranged, respectively, on the front and back sides of the plurality of solar cell assemblies. At least one or each of the front and back plates may be formed of glass (e.g. a glass sheet). The solar module may comprise an encapsulant which may be configured to provide adhesion between the front and back plates and the plurality of solar cell assemblies. In this way, the encapsulant may be arranged between the glass sheet of the solar module, and an insulating optically transparent film of one of the pluralities of solar cell assemblies. Also, the encapsulant may be arranged between the back sheet of the solar module, and an insulating optically transparent film of one of the pluralities of solar cell assemblies. The encapsulant may be configured to prevent the ingress of moisture into the solar module. Accordingly, the encapsulant may be formed of ethylene vinyl acetate (EVA), or any other suitably moisture resistant material.

According to a third aspect of the invention there is provided a method of manufacturing a solar cell assembly according to any one of the preceding statements. The method may comprise arranging the second solar cell so that its back-surface faces in a substantially upward direction. The method may further comprise overlaying a first section of the electrode assembly onto the back surface of the second solar cell such that the second surface of the at least one conductive element is arranged in contact with the back surface. The method may further comprise connecting (e.g. electrically and/or mechanically) the second surface of the at least one conductive element onto the back surface of the second solar cell. The method may comprise overlaying the front surface of the first solar cell onto a second portion of the electrode assembly such that the first surface of the at least one conductive element is arranged in contact with the front surface. The method may further comprise connecting (e.g. electrically and/or mechanically) the first surface of the at least one conductive element onto the front surface of the first solar cell.

As described above, the present invention is particularly beneficial during the process of manufacturing the solar cell assembly (i.e. when coupling the electrode assembly to the first and second solar cells). This is because, when the solar cells are inverted during the connecting step, the smaller contact area of the second surface causes the coating to flow due to gravity towards the contacting surface of the second solar cell (i.e. the back surface). Furthermore, the larger contact area defined by the first surface can retain the coating at the contacting surface of the first solar cell (i.e. the front surface), despite being inverted.

As described above, the solar cells each comprise a back (e.g. backmost) surface and a front (e.g. frontmost) surface being opposite the back surface. Accordingly, the method may comprise arranging a portion of the electrode assembly onto the back surface of the second solar cell to define a back connector. The method may further comprise arranging another portion of the electrode assembly onto the front surface of the first solar cell to define a front connector.

The method may comprise applying heat and/or pressure to (e.g. soldering) the first portion of the conductive elements (i.e. of the front connector) to melt at least a portion of the coating. The portion of melted coating which is arranged on the first surface of the conductive element (i.e. the surface which faces the front surface of the first solar cell) may be configured to form an ohmic contact with the conductive surface of the first solar cell (e.g. the finger electrode), upon which the conductive element is overlaid.

The method may comprise applying heat and/or pressure (e.g. soldering) the second portion of the conductive elements (i.e. of the back connector) to melt at least a portion of the coating. The portion of melted coating which is arranged on the second surface of the conductive element (i.e. the surface which faces the back surface of the second solar cell) may be configured to form an ohmic contact with the conductive surface of the second solar cell (e.g. the finger electrode), upon which the conductive element is overlaid.

The coatings of the conductive elements may be comprised of materials which have melting points which are lower than the materials from which the conductive elements are formed. The coatings of the conductive elements of the front and back connectors may be connected to their respective surfaces of the first and second solar cells separately, or during the same process.

The method may comprise first attaching one of the front and back connectors to the respective first and second solar cells, then attaching the other of the front and back connectors to the other of the respective first and second solar cells.

In situations where the electrode assembly comprises a film (e.g. an insulating and/or optically transparent film), then the method may further comprise attaching the film to the conductive elements (e.g. to form an electrode assembly according to an exemplary arrangement). The method may comprise attaching the film to the conductive elements prior to overlaying, and/or attaching, the conductive elements to the solar cells. The method may comprise heating and/or applying pressure to the film (e.g. laminating) to adhere the film to the conductive elements.

The method of attaching the film to the conductive elements may be performed during the method of coupling the associated conductive elements to the surfaces of the solar cells. In this way, the method of attaching the film to the conductive elements (e.g. the application of heat and/or pressure to the film) may also comprise attaching the film to an associated surface of the solar cell.

In situations where a first portion of the plurality of conductive elements is arranged on a first film portion (e.g. the first connector) and/or a second portion of the plurality of conductive elements is arranged on a second film portion (e.g. the second connector), the first and/or second film portions may be attached to the respective first and/or second portions of the conductive elements.

The method may further comprise arranging (e.g. depositing) a plurality of finger electrodes on at least one, or each, of the front and back surfaces of the first and second solar cells. It will be understood that the method of arranging the finger electrodes may be performed prior to connecting the electrode assembly to the solar cells. The finger electrodes may be formed using a printed material, which enables it to be conveniently deposited onto the surfaces of the solar cells. The printed material may be formed using a printable precursor, such as a conductive paste which may comprise a mixture of metal powder (e.g. Ag, Al, Au powder) and glass frit suspended in a solvent. The printable precursor/conductive paste may be fired, or cured, to form the printed finger electrodes. Alternatively, the finger electrodes may be deposited by various other methods including evaporation, plating, printing etc. The front and back finger electrodes may be deposited simultaneously (i.e. using a single deposition process) or they be deposited separately.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION OF THE DRAWINGS

Embodiments will now be described by way of example only, with reference to the Figures, in which:

FIG. 1 is a close-up sectional side view of a solar module including a solar cell assembly, the solar cell assembly comprising a first solar cell coupled to a second solar cell by an electrode assembly;

FIGS. 2A and 2C are plan views of the top (front) and bottom (back) of the first and second solar cells, respectively, as shown in FIG. 1, respectively;

FIGS. 2B and 2D are transverse sectional views taken through the first and second solar cells, respectively, as shown in FIGS. 2A and 2C;

FIGS. 3A and 3B are close-up sectional views of the first and second solar cells shown in FIGS. 2A to 2D;

FIGS. 4 to 9 are sectional views of alternative conductive elements suitable for use in the electrode assembly shown in FIG. 1;

FIGS. 10A to 15A are side views of a solar cell assembly, showing the different stages of a method of manufacturing the assembly;

FIGS. 10B to 15B are sectional views of the solar cells of the solar cell assembly shown in FIGS. 10A to 15A, showing the different stages of the manufacturing method; and

FIG. 16 is a flowchart illustrating a method of manufacturing the solar cell assembly, as shown in FIGS. 15A and 15B.

### DETAILED DESCRIPTION

Aspects and embodiments of the present disclosure will now be discussed with reference to the accompanying figures. Further aspects and embodiments will be apparent to those skilled in the art.

In the drawings, the thickness of layers, films, elements etc., are exaggerated for clarity. Furthermore, it will be understood that when an element such as a layer, film, region, or substrate is referred to as being “on” another element, it can be directly on the other element or intervening elements may also be present. In contrast, when an element is referred to as being “directly on” another element, there are no intervening elements present.

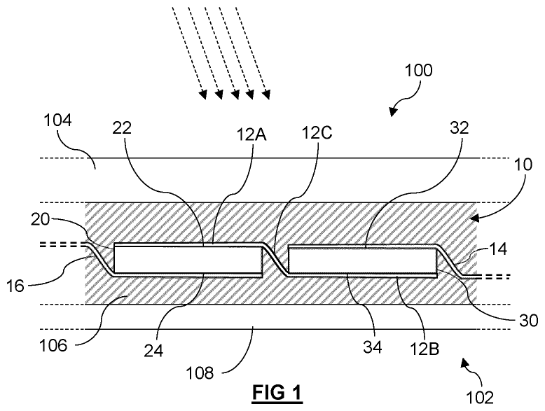

FIG. 1 shows a solar cell assembly 10 according to the present invention, which is arranged within a support assembly 102 of a solar module 100 (e.g. a solar panel). The solar cell assembly 10 includes a first solar cell 20, a second solar cell 30 and an electrode assembly 12 which is arranged to electrically couple a front surface 22 of the first solar cell 20 to a back surface 34 of the second solar cell 30.

The electrode assembly 12 comprises a plurality of conductive elements which are configured to provide an improved electrical pathway between the first and second solar cells 20, 30, whilst also enhancing the light scattering and absorption conditions at the front surface 22 of the first solar cell 20.

A first portion of the electrode assembly 12 is arranged to contact the front surface 22 of the first solar cell 20 to define a front connecting portion, or front connector 12a, of the electrode assembly 12. A second portion of the electrode assembly 12 contacts the back surface 34 of the second solar cell 30 to define a back connecting portion, or back connector 12b, of the electrode assembly 12. The first and second connectors 12a, 12b are electrically coupled together by a third interconnecting portion 12c which bends between the respective upper and lower surfaces 22, 34 of the adjacently positioned solar cells 20, 30 of the solar cell assembly 10.

The solar cell assembly 10 is one of a plurality of solar cell assemblies which are arranged within the support assembly 102. For example, a front surface 32 of the second solar cell 30 is electrically coupled to the back surface of a third solar cell (not shown) by a second electrode assembly 14. Also, a third electrode assembly 16 is provided to couple a back surface 24 of the first solar cell 20 to the front surface of a fourth solar cell (not shown).

It will be understood, for example, that the second and third solar cells in this arrangement are electrically coupled together by the second electrode assembly 14 to define a second solar cell assembly. The plurality of solar cells 20, 30 are thereby coupled together by the electrode assemblies 12, 14, 16 to define a single string.

A front plate 104 of the support assembly 102 comprises a transparent (e.g. glass) sheet which is configured to allow light to pass through into a central chamber 106 in which the solar cell assembly 10 is mounted. The arrows at the top of FIG. 1 show the direction of the solar radiation which is incident upon the solar cell assembly 10.

A back plate 108 of the support assembly 102 is arranged to enclose the solar cell assembly 10 within the central chamber 106. The back plate 108 comprises a reflective sheet which is configured to reflect any light which is incident upon its upper surface, back towards the solar cell assembly 10. The central chamber 106 is filled with an encapsulating material (the shaded area shown in FIG. 1) which prevents ingress of external liquid or gaseous entrants.

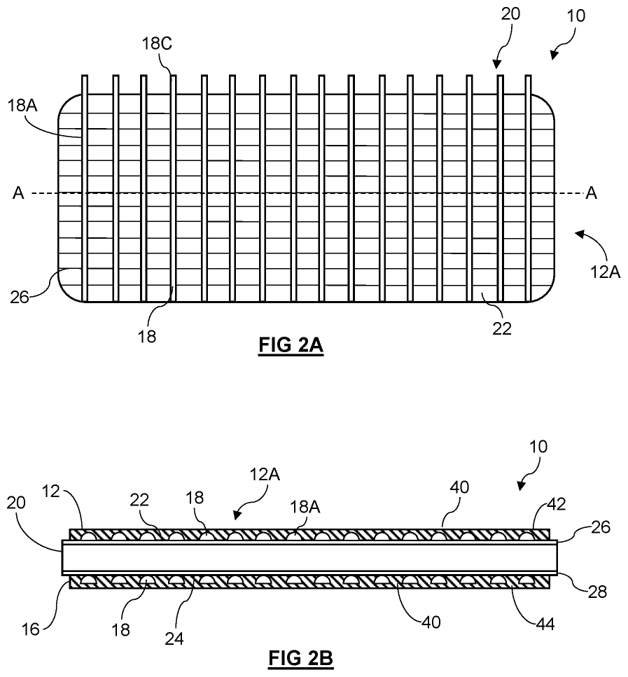

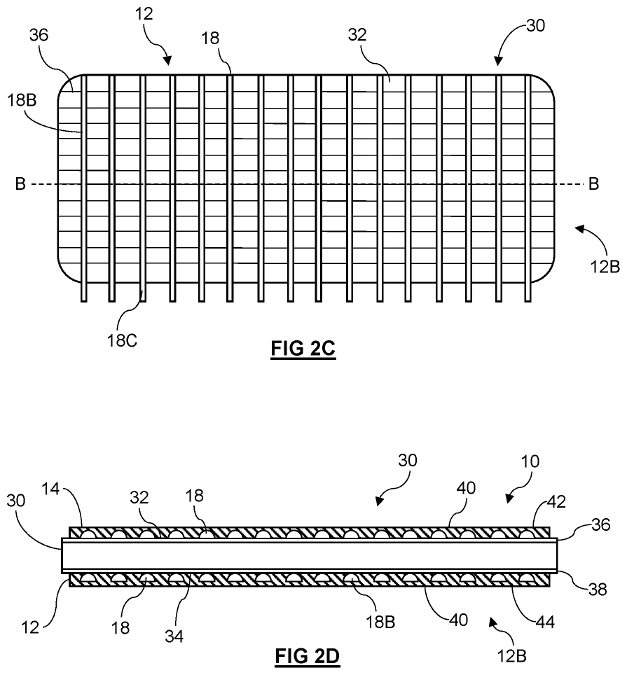

FIGS. 2A and 2C illustrate the top (front) and bottom (back) view of the first and second solar cells 20, 30, respectively, of the solar cell assembly 10. FIGS. 2B and 2D show transverse sectional views of the first and second solar cells 20, 30, respectively, taken along the dashed lines A-A and B-B, as shown in FIGS. 2A and 2C.

Each of the solar cells 20, 30 has a length which is the vertical dimension of FIGS. 2A and 2C, and a width which is the horizontal dimension of FIGS. 2A and 2C. The first and second solar cells 20, 30 are arranged in a common transverse plane (as shown in FIG. 1) such that their width wise and lengthwise dimensions lie in parallel with each other. Each of the front surfaces 22, 32 of the respective solar cells define a surface on which light is incident when the solar cell assembly 10 is in use. The back surfaces 24, 34 each define a surface which is opposite to the respective front surface 22, 32, as shown in FIGS. 2B, 2D.

Each solar cell 20, 30 includes a layered structure (not shown) arranged between its respective front and back surfaces. The layered structure is a multi-layer semiconductor assembly which includes a photovoltaic element (or layer) which is configured to generate electrical charge carriers from the absorption of incident radiation. The front and back finger electrodes 26, 36, 28, 38 are each configured to conduct away the electrical charge carriers generated by the respective solar cell 20, 30.

The first solar cell 20 includes a first plurality of finger electrodes 26 arranged on its front surface 22 (i.e. front finger electrodes), and a second plurality of finger electrodes 28 arranged on its back surface 24 (i.e. back finger electrodes). Similar, the second solar cell 30 includes a first plurality of finger electrodes 36 arranged on its front surface 32, and a second plurality of finger electrodes 38 arranged on its back surface 34.

The electrode assembly 12 comprises a plurality of conductive elements 18, as shown in FIGS. 2A to 2D. The conductive elements are configured to form an ohmic contact with finger electrodes 26, 38 arranged on the front and back surfaces 22, 34 of the first and second solar cells, respectively. The conductive elements 18 each have an integral elongate form, such as a wire, which is formed of an electrically conductive material. For example, the conductive elements 18 are comprise a metallic alloy material, which includes at least one of Ag, Al, Au and Cu. The conductive elements 18 are each arranged within an optically transparent insulating film 40, as shown most clearly in FIGS. 2B and 2D.

A first portion 18a of the plurality of conductive elements 18 defines the front connector 12a of the electrode assembly 12. A second portion 18b of the plurality of conductive elements 18 defines the back connector 12b of the electrode assembly 12. Accordingly, each of the plurality of conductive elements 18 extends from the front connector 12a to the back connector 12b of the electrode assembly 12. A third portion 18c of the plurality of conductive elements 18 is configured to electrically couple together the respective first and second portions 12a, 12b.

The conductive elements 18 are configured, in the third portion 18a, to bend along an axial direction of the conductive element 18 so as to allow the electrode assembly 12 to form an electrical connection between the front and back connectors 12a, 12b.

As described above, the conductive elements 32 are formed of an electrically conductive material such that they are configured to allow electrical charge carriers to flow between the conductive elements 18 and the finger electrodes 26, 38 on the front and back surfaces 22, 34 of the first and second solar cells 20, 30. In this way, each of the conductive elements 18 defines a current collector of the electrode assembly 12. Furthermore, the conductive elements 18 are configured to collect charge carriers from the front finger electrodes 26 of the first solar cell 20 and transport them to the back-finger electrodes 38 of the second solar cell 30, or vice versa.

Each of the conductive elements 18 comprises a width, length, and depth. The length of each conductive elements 18 defines an axial length which is substantially greater than its width and depth. The conductive elements 18 are configured with an asymmetrical cross-section, which leads to an improved electrical connection between the conductive elements 18 and the finger electrodes 26, 38 on the surfaces of the solar cells, as will be explained in more detail below.

With reference to FIGS. 2A to 2D, the arrangement of each of the pluralities of finger electrodes 26, 28, 36, 38 and conductive elements 18 will now be described in more detail.

The pluralities of front and back finger electrodes 26, 28, 36, 38 are arranged to extend across the solar cells 20, 30 in the transverse direction (the horizontal direction in FIGS. 2A, 2C) and are equally spaced apart in the longitudinal direction (the vertical direction in FIGS. 2A, 2C).

The dimensions of each finger electrode 26, 28, 36, 38 are substantially the same as that of every other finger electrode 26, 28, 36, 38. For example, the finger electrodes have a common length, width and depth such that each electrode is arranged to protrude from the surface of the solar cell by the same amount. Furthermore, each of the finger electrodes has a rectangular cross-section (which is measured perpendicular to the electrode's length).

The finger electrodes arranged on each of the front and back surfaces 26, 28, 36, 38 of the solar cells 20, 30 are aligned in parallel with each other, and with a corresponding finger electrode on the opposite side of the solar cell. For example, each one of the finger electrodes 26 arranged on the front surface 22 of the first solar cell 20 is longitudinally aligned with a corresponding finger electrode 28 from the plurality of back finger electrodes 28. As shown in FIGS. 2A and 2C, each of the pluralities of front and back finger electrodes 26, 28, 36, 38 comprises twelve electrodes. However, it is to be understood that in some other embodiments, the number of front and back finger electrodes 26, 28, 36, 38 may be different, without departing from the scope of the present invention.

The number of conductive elements 18 of the electrode assembly 12 is between 4 and 20. According to the embodiment described herein the first electrode assembly 12 has between fourteen and eighteen conductive elements 18, for example sixteen conductive elements 18 as shown in FIGS. 2A to 2D. However, it will be appreciated that, in some other embodiments, a different number of conductive elements may be present, without departing from the scope of the present invention.

The first and second portions 18a, 18b of the plurality of conductive elements 18 are parallel and extend lengthwise relative to the front and back surfaces 22, 34 of the solar cells, in a longitudinal direction (the vertical direction in FIG. 2A). The conductive elements 18 are also equally spaced apart in a transverse direction relative to the front and back surfaces 22, 34 (the horizontal direction in FIG. 2A) to define longitudinal-extending spaces between the conductive elements 18. Accordingly, each one of the first and second portions 18a, 18b defines an array of parallel, transversely spaced conductive elements 18.

Each of the first portions 18a of the plurality of conductive elements 18 are axially aligned with the corresponding second portions 18b of the conductive elements 18 of the same electrode assembly 12. Also, the second portions 18b of conductive elements 18 of the first electrode assembly 12 are axially aligned with the first portions 18a of the conductive elements 18 of the second electrode assembly 14, with the second solar cell 30 interposed between.

According to the above described arrangement, it will be understood that the pluralities of front and back finger electrodes 26, 38 are arranged perpendicular to the first and second portions 18a, 18b of the plurality of conductive elements 18, as shown in FIGS. 2A and 2C.

The finger electrodes 26, 28, 36, 38 are formed of an electrically conductive material, which is formed of a metallic alloy comprising Ag. The electrically conductive material is a printed material, which enables the finger electrodes to be conveniently deposited onto the respective surfaces of the solar cells. The printed material is formed using a printable precursor, such as a conductive paste, which comprises a mixture of silver metal powder and glass frit suspended in a solvent. The conductive paste may be fired, or cured, to form the finger electrodes.

As described above, the electrode assembly 12 comprises an insulating and optically transparent film 40 in which the conductive elements 18 are arranged. The first and second portions 18a, 18b of the plurality of conductive elements 18 are each arranged in separate film portions, which are arranged on the front and back surfaces 22, 34 of the respective solar cells. For example, the front connector 12a comprises a first film portion which defines a front film portion 42 and the back connector 12b comprises a second film portion which defines a back-film portion 44. However, it is noted that the conductive elements 18 in the third portion 18c are free from any film covering.

According to an exemplary arrangement of the solar cell assembly 10, each of the first and second portions 18a, 18b of the conductive elements 18 is attached to a surface of its respective film 42, 44 that faces the solar cell. This “solar cell-facing” surface of each film 42, 44 is coated with an adhesive which adheres the conductive elements to their respective films 42, 44.

With reference to FIGS. 2B and 2D, in the case of the front connector 12a, the film 42 is arranged to contact the front surface 22 of the solar cell in the areas in-between the conductive elements 18 and the front finger electrodes 26. The back-film portion 44 is configured in the same way for the back connector 12b.

In an exemplary arrangement of the solar cell assembly 10 each of the films 42, 44 is configured to at least partially (e.g. completely) envelope, or surround, the respective conductive elements 18 and the respective finger electrodes 26, 38, as shown in FIGS. 2B and 2D.

The front and back film portions 42, 44 are arranged to provide adhesion between the solar cells and the conductive elements 18 so that the conductive elements are correctly arranged on the solar cells (i.e. aligned with the finger electrodes). In an exemplary embodiment, the front and back film portions 42, 44 may not fully cover the respective surfaces of the solar cells.

Whilst the front and back film portions 42, 44 shown in the drawings comprise substantially planar bottom and top surfaces, respectively. It will be understood that the films may be configured to conform to the structural components of solar cells and/or conductive elements. For example, the film 40 of the back connector 12b may conform to the finger electrodes 38 and conductive elements 18 which are arranged on the back surface 34 of the solar cell 30. According to this exemplary arrangement, the film 40 may be comprised of elongate channels recessed towards the solar cell in the regions of the back surface 34 in-between conductive elements, and may form ridges/protuberances over the structures electrodes (e.g. finger electrodes and conductive elements) where they are present.

The front and back film portions 42, 44 are applied with heat and pressure onto the respective surfaces of the solar cells so that the films will conform to the finger electrodes and conductive elements arranged thereon.

According to an alternative exemplary arrangement, the films 40 may comprise channels, arranged on their respective solar cell facing surfaces. The channels may be configured to provide a tight fit around the corresponding conductive elements and finger electrodes.

The front and back film portions 42, 44 may be thinner than the conductive elements 18. For example, the conductive elements 18 may have a thickness (i.e., depth) of at least 200 μm and up to 400 μm (e.g., between 0.2 mm and 0.4 mm), whereas the films have a thickness of at least 70 μm and up to 120 μm (e.g., between 0.07 mm and 0.12 mm).

The front and back film portions 42, 44 are each formed of a polymer material having a high ductility, good insulating characteristics, optical transparency and thermal stability, resistance to shrinkage. An exemplary polymer material is comprised of modified ethylene tetrafluoroethylene.

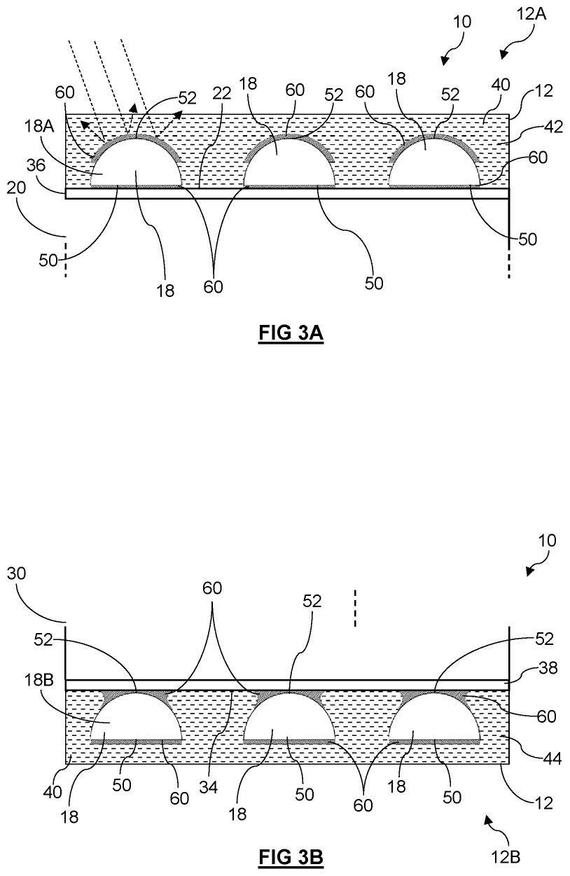

With reference to FIGS. 3A, 3B and 4 to 9, the configuration of the conductive elements 18 will now be described in more detail. In an exemplary arrangement, the conductive elements 18 each have a semi-circular transverse cross-sectional shape (i.e. transverse to the axial length of the conductive element 18), as shown in FIGS. 3A, 3B, 4 and 7. However, the conductive elements 18 may be configured with different cross-sectional shapes, as shown in FIGS. 5, 6, 8 and 9, without departing from the scope of the present invention.

Each of the conductive elements 18 comprises a first surface 50 which is configured to electrically contact the front surface 22 of the first solar cell 20, as shown in FIG. 3A. Each conductive element 18 also comprises a second surface 54 configured to electrically contact the back surface 34 of the second solar cell 30, as shown in FIG. 3B.

At least a portion of each of the first and second surfaces 50, 52 comprises a coating 60 which is configured, when in use, to solder the respective first and second surfaces 50, 52 to a surface of the solar cells 20, 30 upon which they are overlaid.

It will be appreciated that FIG. 3A shows the first portion 18a of the conductive elements 18 on the front surface 22 of the first solar cell 20 (i.e. the front connector 12a of the electrode assembly 12), whereas FIG. 3B illustrates the second portion 18b of the same conductive elements 18 on the back surface 34 of the second solar cell 30 (i.e. the back connector 12b of the electrode assembly 12).

The first and second surfaces 50, 52 define two distinct longitudinal surfaces of the conductive element 18 (i.e. the surfaces which extend in a longitudinal direction of the conductive element). In particular, the first and second surfaces 50, 52 define upper or lower surfaces of the conductive element 18. As such, the first surface 50 is arranged on the opposite side of the conductive element 18 from the second surface 52.

The conductive elements 18 each comprise a first surface 50 which is substantially flat. The first surface 50 of the conductive element portion 18a is configured with a planar surface which faces, and lies parallel to, the front surface 22 of the first solar cell 20, as shown in FIG. 3A. The flat first surface 50 is particularly advantageous in situations where the solar cells are inverted during their connection to the electrode assembly 12. In such situations, the first surface 50 of the conductive elements 18 are arranged to face in a substantially upward direction (e.g. vertically up), as will be described in more detail below. When heat and/or pressure is applied to the conductive elements 18 (e.g. lamination) to form the connection with the front solar cell surface 22, the coating 60 is supported on the flat surface and thereby prevented from flowing, due to gravity, away from the contact interface with the solar cell surface.

In contrast to the first surface 50, the conductive elements' second surfaces 52 are substantially curved, as shown in FIG. 3B. The convex shape of the second surface 52 defines a cross-sectional arc whose ends terminate at the edges of the first surface 50. In this way, the conductive elements 18 each comprise a semi-elliptical cross section, as shown in FIGS. 3A and 3B.

The contact area of the first surface 50 is defined by a width of the first surface 50 which forms the electrical contact with the front surface 22 of the first solar cell 20 (e.g. the front finger electrode 36). Accordingly, the contact area of the first surface 50 is substantially defined by the width of the coating 60 which forms between the first surface 50 and the front surface 22 of the solar cell, as shown by the in FIG. 3A.

The contact area of the second surface 52 is defined by a width of the second surface 52 which forms an electrical contact with the back surface 34 of the second solar cell 30 (e.g. the back-finger electrode 38). In particular, the contact area of the second surface 52 is defined by the width of the coating 60 which forms between the second surface 52 and the back surface 34 of the solar cell, as shown by the in FIG. 3B. Accordingly, since the first surface 50 has a wider cross-sectional width (i.e. contact width) than the second surface 52, the contact width of the first surface 50 is also greater than the contact area defined by the second surface 52.

The curved configuration of the second surface 52 causes the coating 60 to flow towards the upper central point of the second surface 52. This arrangement of the second surface 52 also causes the coating 60 to wet onto the back surface 34 of the second solar cell 30, which narrows the width of the contact area between the conductive element 18 and the second solar cell 30. Considering the front connector 12a, the curved second surface 52 also provides a light scattering surface on the front surface 22 of the first solar cell 20, as illustrated by the dashed arrows in FIG. 3A

It will be understood that the first and second contact areas are also defined, at least in part, by the length of each conductive element 18 which is configured to overlay the respective front and back surfaces 22, 34 of first and second solar cells 20, 30 (i.e. the length of the first and second conductive element portions 18a, 18b associated with the front and back connectors 12a, 12b , respectively).

The electrode assembly 12 is configured such that the length of the portion 18a of the conductive elements 18 which overlays the front surface 22 of the first solar cell 20 is equal to the length of the conductive element portion 18b which overlays the back surface 34 of the second solar cell 30. Accordingly, the difference in the respective contact areas is defined by the contact width of the respective first and second surfaces 50, 52 of the conductive elements 18.

According to an exemplary arrangement, the conductive elements 18 may comprise a third and a fourth surface 54, 56 arranged between the first and second surfaces 50, 52, as shown in FIGS. 5, 6, 8 and 9. The fourth surface 56 is arranged opposite the third surface 54, and they each space apart the first surface 50 from the second surface 52 to define a depth of the conductive element 18.

According to each of these exemplary arrangements, the second surfaces 52 are configured to be substantially flat. The flat second surface 52 is arranged to be parallel to the first surface 50 and the respective front and back surfaces 22, 34 of the first and second solar cells 20, 30. Compared to the curved second surface, the flat second surface 52 provides a more robust electrical contact with the second solar cell 30 whilst still providing some light scattering when arranged on the front surface of the first solar cell 20.

The third and fourth surfaces 54, 56 may be configured with a convex curved surface, as shown in FIGS. 5 and 7. In these arrangements, the conductive element 18 comprises a cross sectional shape which defines a truncated semi-circle. Alternatively, the third and fourth surfaces 54, 56 may be substantially flat such that the conductive element's cross-section defines a truncated triangle, as shown in FIGS. 6 and 9.

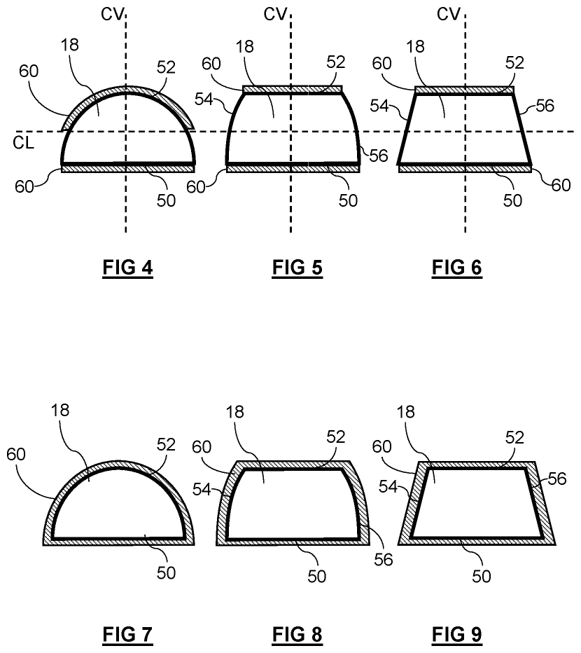

The conductive elements 18 are configured such that they each comprise a cross sectional shape which is non-symmetrical about a central lateral plane CL of the conductive element 18, as shown by the dashed horizontal line in FIGS. 4 to 6. The central lateral plane CL defines a plane which extends in a width wise, or horizontal, direction through the longitudinal axis of the conductive element 18. The conductive elements 18 are also configured such that they comprise a cross sectional shape which is symmetrical about a central vertical plane CV of the conductive element 18. The central vertical plane CV defines a plane which extends in a depth wise, or vertical, direction through the longitudinal axis of the conductive element 18, as shown by the vertical dashed lines in FIGS. 4 to 6.

In each of the exemplary arrangements shown in FIGS. 4 to 9, the coating 60 is configured to substantially cover the first and second surfaces 50, 52. As shown in FIG. 4, the coating 60 is arranged to only cover the portion of the second surface 52 which is configured to make contact with a solar cell surface (e.g. the back surface 34 of the second solar cell 30). In the exemplary arrangements where the conductive elements 18 comprise a third and fourth surface 54, 56, then the coating 60 is only arranged on the first and second surfaces 50, 52, as shown in FIGS. 5 and 6. Alternatively, each of the surfaces of the conductive element may be coated in the coating 60, as shown in FIGS. 7 to 9.

The coating 60 is an electrically conductive material having a melting point which is lower than that of the conductive element 18. The coating 60 comprises a metal alloy formed of at least two or more components, such as a lead based, tin based and bismuth-based alloy. Alternatively, the coating 60 may comprise a 2-phase, 3-phase, or more complex metal alloy, as would be understood by the skilled person.

In the exemplary arrangements shown in FIGS. 3A, 3B and 4 to 9, each conductive element 18 is configured with a constant cross-section along its length. Each conductive element 18 is arranged such that the first and second surfaces 50, 52 maintain their respective positions on the conductive element 18, as the element extends and connects between the first solar cell 20 and the second solar cell 30. In this way, each conductive element 18 is configured so as not to comprise any axial twists or turns along its length.

Each of the conductive elements 18 is formed from a single wire portion (i.e. the first and second portions 18a, 18b of each conductive element 18 are integrally formed with each other). In this way, the conductive elements 18 provide a direct electrical connection between the first and second solar cells 20, 30, which increases the flow of current therebetween. Configuring the conductive elements in this way removes the need to provide separate connections (such as copper ribbons) between neighbouring solar cells, which thereby reduces the number and complexity of manufacturing steps required to fabricate the solar cell assembly 10.

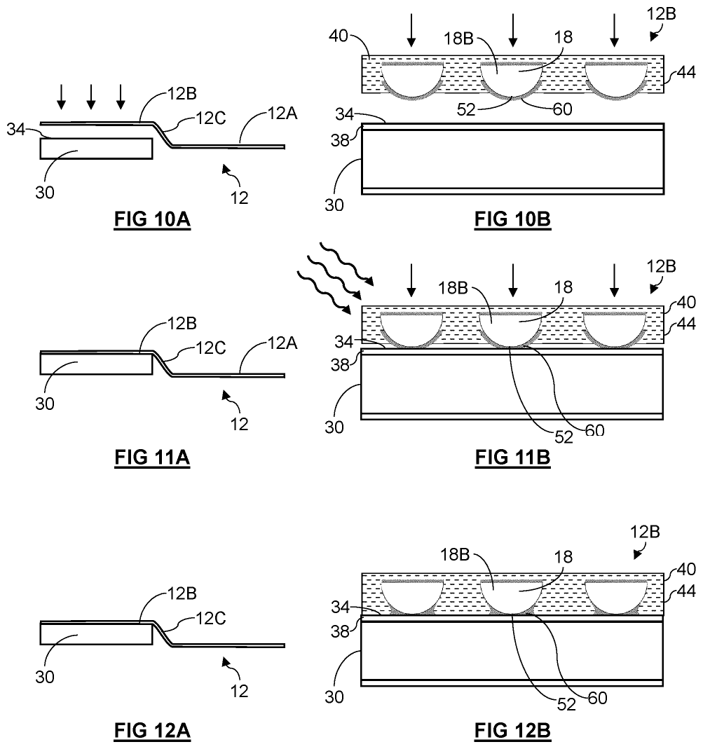

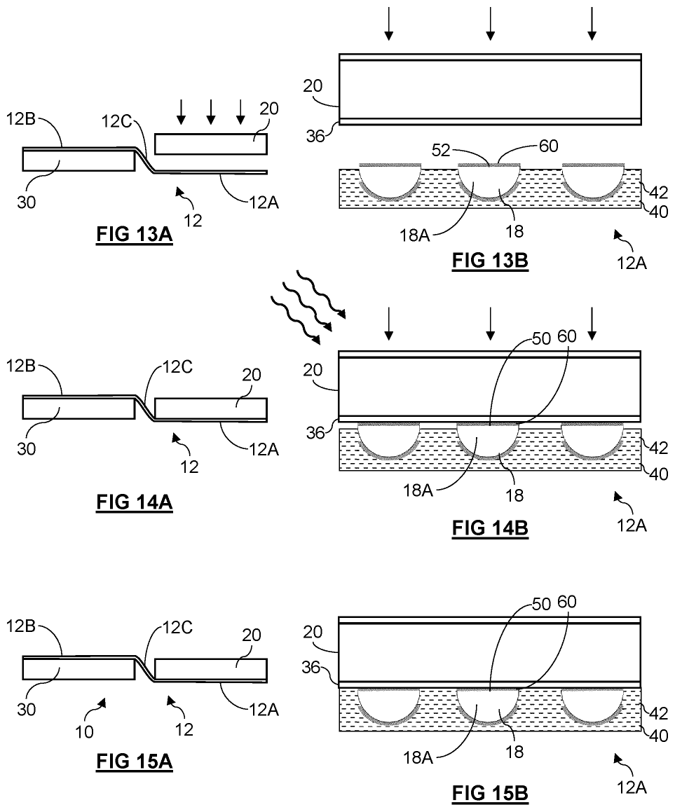

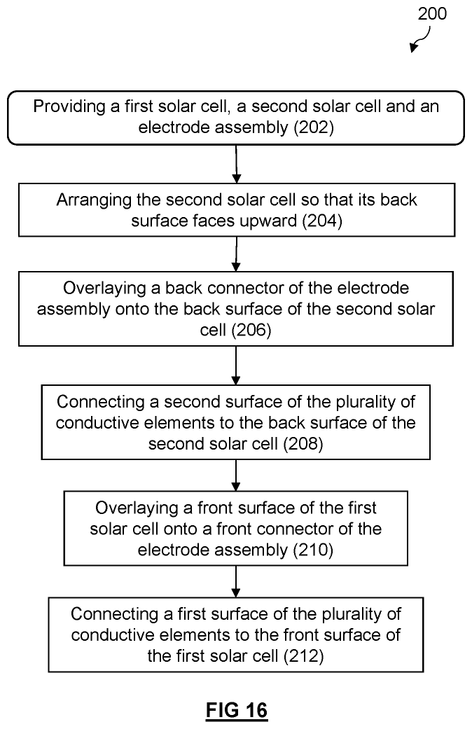

An exemplary method of manufacturing the solar cell assembly 10 will now be described with reference to FIGS. 10A to 15B, which illustrate the steps of the manufacturing method. Reference will also be made to FIG. 16, which shows a flow chart of the corresponding method steps.

The method commences with a first step 202 in which there is provided a first solar cell 20, a second solar cell 30 and an electrode assembly 12, as described above. Prior to the first step 202, the solar cells are manufactured in a conventional manner as would be understood by the person having ordinary skill in the art. In particular, the method includes configuring each of the solar cells with a conductive surface (or conductive portion) on their respective front and back surfaces. For example, this may be achieved through the deposition of electrically conductive material onto the front and back surfaces 22, 34 of the first and second solar cells 20, 30 to form the pluralities of front and back finger electrodes 36, 38, respectively.

According to an exemplary method, the finger electrodes 36, 38 are deposited onto their respective surfaces using a screen-printing process. The screen-printing process includes laying down a printable precursor onto the layered structure surface through a screen, or mask. The printable precursor comprises a metal paste which is obtained by mixing metal powder together with glass frit in the presence of a suitable solvent. Openings in the mask determine the respective arrangement and dimensions of the printed features (i.e. the finger electrodes). Once the printable precursor is provided onto the solar cell surface, it is then fired in a furnace to form the corresponding finger electrodes.

The electrode assembly 12 may be formed by arranging a plurality of conductive elements 18 together with respective first and second portions of film 42, 44 in order to define the front and back connector 12a, 12b of the electrode assembly 12.

Once the plurality of finger electrodes 36, 38 are deposited onto the surfaces of the first and second solar cells 20, 30, the electrode assembly 12 can be connected to the solar cells 20, 30 to define a solar assembly 10, according to the present invention.

In step 204, the second solar cell 30 is arranged so that its back surface 34 faces upward, as shown in FIGS. 10A and 10B, for example. Once the second solar cell 30 is inverted, then in step 206 the back connector 12b of the electrode assembly 12 is overlaid onto the back surface 34 of the second solar cell 30. Accordingly, the conductive elements 18 are overlaid onto the back surface 34 such that they sit perpendicular to the finger electrodes 38, as shown in FIG. 11B. As a result of method step 206, the second surfaces 52 of the conductive elements 18 are brought into contact with the back-finger electrodes 34 of the solar cell.

In step 208, the second surface 52 of the plurality of conductive elements 18 is connected to the back surface 34 of the second solar cell 30. This method step involves heating and/or applying pressure to the conductive elements 18 in the second connector 12b to bond the coating 60 to the second solar cell's back surface 34 under a compressive force, as illustrated in FIG. 11B.

The application of heat and pressure causes the coating 60 on the second surface 52 of the conductive elements 18 to flow due to gravity towards the back surface 34 of the second solar cell 30. The coating 60 wets against the solar cell surface. Also, the curvature of the conductive element's second surface 52 causes the coating 60 to build-up, or pool, at the interface between the solar cell and the conductive element.

Once the coating has cooled and solidified, it forms an ohmic contact with the underlying back-finger electrodes 38, as shown in FIG. 12B. The application of heat and pressure also laminates the back film 44 onto the back surface 34 of the solar cell 30.

The method proceeds with step 210 in which the first solar cell 20 is inverted and overlaid onto the front connector 12a, as shown in FIGS. 10A and 10B. In so doing, the first surfaces 50 of the conductive elements' front portions 18a are brought into contact with the front surface 22 of the first solar cell 20.

In step 212, the first surfaces 50 of the plurality of conductive elements 18 are then connected to the front surface 22 of the first solar cell 20. Like step 208, the method involves heating and/or applying pressure to the conductive elements 18 of the first connector 12a to physically bond them to the first solar cell's front surface 22 under a compressive force, as illustrated in FIG. 14B. The application of heat and pressure cause the coating 60 on the conductive elements' first surfaces 50 to melt and then wet against the first solar cell's front surface 22. The planar first surface 50 is configured to retain the molten coating 60 in position at the interface with the solar cell 20 whilst the coating 60 cools and solidifies to form an ohmic contact therebetween. The application of heat and pressure also laminates the front film 42 onto the first solar cell's front surface 22, as shown in FIG. 15B.

In embodiments, the front plate 104 of the solar module 100 is made of glass whilst the rear plate 108 is made from a lighter polymer sheet. In this case, a further advantage of assembling the solar cell assembly 10 with the inverted solar cells 20, 30 is that it's easier to build up the solar assembly 10 onto the heavier front plate 104 and then cover it with the lighter back plate 108. This reduces the risk of damaging the solar module 100 compared with having to arrange the heavier glass front plate 104 into position on top of a pre-assembled solar assembly 10.

It will be appreciated that at least some of the above described method steps may be undertaken concurrently or in any order. For example, the method steps which involve inverting and arranging the first and second solar cells 20, 30 with respect to the electrode assembly 12 may take place at substantially the same time. Similarly, the front and back connectors 12a, 12b may also be connected to the respective front and back surfaces 22, 34 of the first and second solar cells 20, 30 at the same time.

As a result of the above described method, the front and back connectors 12a, 12b of the electrode assembly 12 are both mechanically and electrically coupled to the respective first and second solar cells 20, 30 to form a solar cell assembly 10 according to the present invention.

It will be understood that the invention is not limited to the embodiments above described and various modifications and improvements can be made without departing from the concepts described herein. Except where mutually exclusive, any of the features may be employed separately or in combination with any other features and the disclosure extends to and includes all combinations and sub-combinations of one or more features described herein.

### FEATURE LIST

Solar cell assembly 10
Electrode assembly 12, 14, 16
Front connector 12a
Back connector 12b
Interconnecting portion 12c
Conductive element 18
First portion of the conductive elements 18a
Second portion of the conductive elements 18b
Third portion of the conductive elements 18c
First solar cell 20
Front surface 22
Back surface 24
Front finger electrodes 26
Back finger electrodes 28
Second solar cell 30
Front surface 32
Back surface 34
Front finger electrodes 36
Back finger electrodes 38
Film 40
Front film portion 42
Back film portion 44
Conductive element-first surface 50
Conductive element-second surface 52
Conductive element-third surface 54
Conductive element-fourth surface 56
Coating 60
Solar module 100
Support assembly 102
Front plate 104
Central chamber 106
Back plate 108
Method steps 200 to 212

1. An electrode assembly for connecting a front surface of a first solar cell to a back surface of a second solar cell, the electrode assembly comprising:
a plurality of conductive elements, wherein at least one of the conductive elements comprises:
a first surface for contacting the front surface of the first solar cell; and
a second surface for contacting the back surface of the second solar cell, the second surface being arranged opposite the first surface;
wherein at least a portion of each of the first and second surfaces comprises a coating for connecting the respective surfaces of the at least one conductive element to a surface of the solar cell;
wherein the second surface is configured to define a contact area which is substantially smaller than the contact area defined by the first surface.

2. The electrode assembly according to claim 1, wherein the second surface is substantially curved.

3. The electrode assembly according to claim 2, wherein the second surface curves outwardly from the conductive element.

4. The electrode assembly according to claim 3, wherein the at least one conductive element comprises a cross section shaped as an elliptical segment.

5. The electrode assembly according to claim 1, wherein the second surface is substantially flat.

6. The electrode assembly according to claim 1, wherein the first surface is substantially flat.

7. The electrode assembly according to claim 6, wherein the first surface is substantially parallel to the second surface.

8. The electrode assembly according to claim 1, wherein the at least one conductive element comprises a third surface arranged between the first and second surfaces, the third surface being configured to space apart the first surface from the second surface.

9. The electrode assembly according to claim 8, wherein the third surface is substantially flat.

10. The electrode assembly according to claim 8, wherein the third surface is substantially curved.

11. The electrode assembly according to claim 10, wherein the third surface curves outwardly from the conductive element.

12. The electrode assembly according to claim 1, wherein the coating is configured to substantially cover the first and second surfaces.

13. The electrode assembly according to claim 12, wherein the coating is configured to substantially cover each of the conductive element's surfaces.

14. The electrode assembly according to claim 1, wherein at least a portion of the conductive elements are arranged in or on an insulating and optically transparent film, wherein at least a portion of at least one of the first and second surfaces of the at least one conductive element is exposed from the film to form an ohmic contact with the respective front and back surfaces of the first and second solar cells.

15. A solar cell assembly comprising a first solar cell, a second solar cell and an electrode assembly according to claim 1, wherein the plurality of conductive elements are configured to electrically couple a front surface of the first solar cell with a back surface of the second solar cell.

16. A method of manufacturing a solar cell assembly according to claim 15, the method comprising:
arranging the second solar cell so that its back surface faces in a substantially upward direction;
overlaying a first section of the electrode assembly onto the back surface of the second solar cell such that the second surface of the at least one conductive element is arranged in contact with the back surface;
connecting the second surface of the at least one conductive element onto the back surface of the second solar cell;
overlaying the front surface of the first solar cell onto a second section of the electrode assembly such that the first surface of the at least one conductive element is arranged in contact with the front surface; and
connecting the first surface of the at least one conductive element onto the front surface of the first solar cell.
